(19) United States
(12) Patent Application Publication
(10) Pub. No.: US 2006/0097219 A1
(43) Pub. Date: May 11, 2006

(54) High selectivity slurry compositions for chemical mechanical polishing

(75) Inventors: Benjamin A. Bonner, San Jose, CA (US); Anand N. Iyer, Santa Clara, CA (US); Olivier Thanh Nguyen, Santa Clara, CA (US); Donald Kim Aun Chua, Sunnyvale, CA (US); Christopher Heung-Gyun Lee, Alameda, CA (US); Shijian Li, San Jose, CA (US)

Correspondence Address: APPLIED MATERIALS, INC.;Legal Affairs Department, Patent Counsel, M/S 2061, P.O. Box 450A, Santa Clara, CA, 95052, US

(73) Assignee: Applied Materials, Inc., Santa Clara, CA (US)

(21) Appl. No.: 11/258,466

(22) Filed: Oct. 24, 2005

Related U.S. Application Data
(60) Provisional application No. 60/626,272, filed on Nov. 8, 2004.

(51) Int. Cl. C09K 13/00; H01L 21/461

(52) U.S. Cl. 252/79.1; 252/79.4; 438/692

(57) ABSTRACT

A chemical-mechanical polishing composition that includes less than about 1% wt. abrasive, an additive, and water, where a weigh percent of the additive is greater than a weight percent of the abrasive. Also, a method of polishing a semiconductor substrate in a shallow trench isolation process, the method including contacting the substrate with a polishing pad of a polishing apparatus while applying a high selectivity slurry to the polishing pad, where the slurry comprises less than about 1% wt. abrasive, an additive, and water, and where a weigh percent of the additive is greater than a weight percent of the abrasive. Also, a method of making a chemical-mechanical polishing slurry composition, the method including adding together an abrasive, an additive and water to form the slurry, where a weigh percent of the additive is greater than a weight percent of the abrasive, and the abrasive and additive together comprise less than 2% by wt. of the slurry.

### CROSS-REFERENCES TO RELATED APPLICATIONS

This application claims the benefit of U.S. Provisional Application No. 60/626,272, filed Nov. 8, 2004, and entitled “HIGH SELECTIVITY SLURRY COMPOSITIONS FOR CHEMICAL MECHANICAL POLISHING,” the entire contents of which are herein incorporated by this reference

### BACKGROUND OF THE INVENTION

Integrated circuits (IC) such as dynamic random access memory, flash memory, etc. are made up of millions of elements that get formed in a semiconductor substrate. Shallow trench isolation (STI) is a widely used process in IC fabrication that helps isolate the individual elements (e.g., transistors, interconnects, etc.) of the IC device. For example, STI processes can include the deposition of silicon nitride on silicon oxide (e.g., thermally grown SiO₂) followed by the etching of a shallow trench into the substrate using a mask. A layer of silicon oxide may then be deposited into the trench so that the trench forms an area of insulated dielectric that acts to isolate the IC elements from each other, preventing adjacent elements from shorting and reducing the cross-talk between elements.

Once the trenches are formed, excess deposited oxide needs to be removed and the topography planarized to prepare the foundation for the next level of IC device elements. The silicon nitride may act as a resist or stop layer that prevents the removal of silicon oxide which forms part of the device pattern.

One widely used technique to remove the excess oxide is chemical-mechanical polishing (CMP). In a typical CMP process, the substrate is placed in contact with a rotating polishing pad on a polishing device. A carrier applies pressure to the backside of the substrate to press the pad at substrate together as the pad and table are rotated. The process also includes introducing an abrasive, chemically reactive solution (sometimes called a “CMP slurry”) to the pad during polishing. The components of the CMP slurry may include abrasive particles and additives that interact with the substrate to remove the excess oxide. Polishing the substrate in the presence of the slurry may continue until all the excess oxide is removed and the oxide layer reaches the desired film planarity and thickness.

When removing oxide and planarizing oxide layers with CMP, it is useful for the slurry to have a high degree of selectivity towards one film material over another. For example, when the slurry is used to remove excess oxide in the presence of a nitride protecting layer, a slurry should be chosen that removes the oxide at a higher removal rate than the nitride. Such a slurry is commonly termed selective to silicon nitride.

Selective slurries that have a higher removal rate for silicon oxide than silicon nitride are commercially available. These conventional high selectivity slurries typically include 1 to 5 wt. % of a cerium oxide abrasive and an equal amount of additive (e.g., surfactant solution) in de-ionized water. A specific example of a high selectivity slurry for STI applications is Seimicron CES 333 1.0 made by Seimi Chemical (a subsidiary of Asahi). Seimicrom CES 333 1.0 contains 1 wt. % cerium oxide abrasive and 1 wt. % aqueous additive solution in de-ionized water. While the slurry demonstrates high silicon nitride selectivity for CMP in STI applications, its consumption at 100 to 300 m/min contributes significantly to process costs of the CMP step.

Higher concentrations of abrasive can also result in a high scratch count on the polished substrate surface. Lowering the concentration by diluting the slurry with more water, however, has unpredictable effects on selectivity (e.g., oxide film removal rate). Sometimes diluting the slurry with more water results in the oxide being removed too quickly causing dishing, and other times results in the oxide being removed too slowly lowering efficiency. Thus, there is a need for selective CMP slurries with lower abrasive concentrations and more controlled selectivity.

### BRIEF SUMMARY OF THE INVENTION

Embodiments of the invention include a chemical-mechanical polishing composition that includes less than about 1% wt. abrasive, an additive, and water, where a weigh percent of the additive is greater than a weight percent of the abrasive.

Embodiments of the invention also include methods of polishing a semiconductor substrate in a shallow trench isolation process. The polishing methods include the step of contacting the substrate with a polishing pad of a polishing apparatus while applying a high selectivity slurry to the polishing pad. The slurry includes less than about 1% wt. abrasive, an additive, and water, where a weigh percent of the additive is greater than a weight percent of the abrasive.

Embodiments of the invention further include methods of making a chemical-mechanical polishing slurry composition. The methods may include the step of adding together an abrasive, an additive and water to form the slurry, where a weigh percent of the additive is greater than a weight percent of the abrasive, and the abrasive and additive together make up less than 2% by wt. of the slurry.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

FIG. 1 is a flowchart that shows steps in an exemplary method of making a chemical-mechanical polishing composition;

FIG. 2 is a flowchart that shows steps in a chemical-mechanical polishing method according to an embodiment of the invention; and

FIG. 3 is a schematic of a chemical-mechanical polishing apparatus that may be used with the slurry compositions and methods of the invention.

### DETAILED DESCRIPTION OF THE INVENTION

The present invention provides improved high selectivity slurry compositions for chemical-mechanical polishing of substrate wafers. The slurry compositions include aqueous mixtures of abrasives and additives where the abrasive concentration is less than about 1% wt., and where the weigh percent of the additive is greater than a weight percent of the abrasive. For example, the weight percent of the additive may be about 1.5 times or more than the weight percent of the abrasive. Because the present slurry compositions have a lower abrasive concentration than conventional slurries (typically 1% to 5% wt. of abrasive and an equal % wt of additive) less abrasive may be used during a CMP process. For example a high selectivity slurry of the present invention having 0.25% wt. abrasive and 0.5% wt. additive uses half the additive of a conventional slurry and a quarter the abrasive. Since the present slurries require less abrasive and additive than conventional slurries, costs can be reduced. The cost savings is increasingly significant as the slurry consumption rate goes up as substrate wafers get larger. For example, while CMP processes on 200 mm wafers typically consume about 200 ml/min of slurry, processes for 300 mm wafers consume about 250-300 ml/min.

Not only does this reduce the cost of the CMP process, it also reduces the number of abrasive particles that scratch the substrate surface (i.e., the scratch count). As the size of the device elements on the substrate shrinks, and their complexity increases, these abrasive scratches can have an increasing effect on device performance and defect rates. Thus, CMP slurries that reduce the scratch counts on the substrate increasingly improve the quality of the IC devices produced.

While the present slurries have a lower weight percent than conventional CMP slurries, they are not made by simply diluting a conventional slurry with additional water. In high selectivity slurries, dilution does not have the same effect on the abrasive and the additive with respect to their abilities to remove oxide deposits during polishing. The additive, typically a surfactant, lowers the oxide removal rate, while the abrasive enhances the removal rate. Dilutions that reduce the concentration of the slurry by half or less have a greater impact on the ability of the additive to reduce the removal rate than on the ability of the abrasive to increase the rate. Consequently, simple dilution of a conventional CMP slurry with water can increase its abrasiveness to the point where significant amounts of a protective nitride layer gets eroded, and dishing degrades the planarity of the substrate surface.

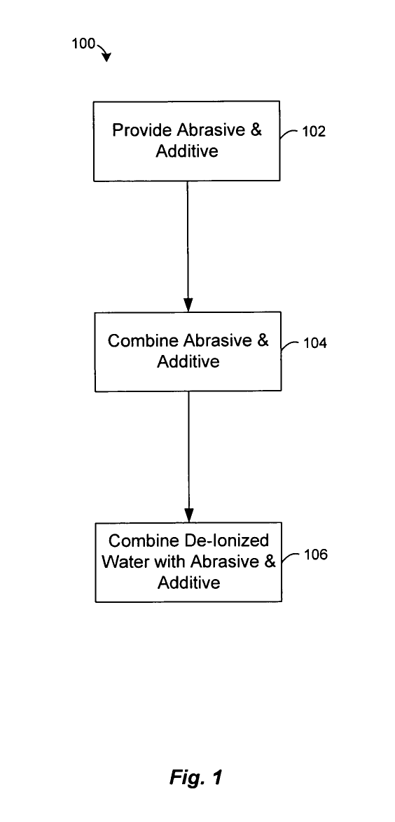

The present high selectivity CMP slurries may be produced from mixtures of an abrasive, an additive, water, and (optionally) some additional components. FIG. 1 is a flowchart relating to steps in an exemplary method 100 of making the present chemical-mechanical polishing compositions. The method includes providing the abrasive and additive components of the slurry in step 102, and combining them such that the weight percent of the additive is greater than a weight percent of the abrasive (e.g., about 1.5 times or more than the weight percent of the abrasive) in step 104. The abrasive may be an abrasive that is selective for removing silicon oxide deposits on the substrate surface at a higher rate than silicon nitride. Removal rates ratios of oxide to nitride may be greater than about 5 to 1 in some embodiments, and greater than about 20 to 1 in some embodiments. For example, a selective abrasive that removes nitride deposits from the substrate at a rate of about 50 Å/min, would remove oxide deposits at about 250 Å/min or more in some embodiments, and greater than 1000 Å/min in some embodiments. Similarly, a selective abrasive that removes nitride at 100 Å/min would remove oxide at about 500 Å/min or more in some embodiments, and from about 1000 Å/min to about 5000 Å/min in some embodiments. Abrasive materials may include cerium oxide (i.e., ceria) alone, or in combination with other metal oxides such as alumina, titania, zirconia, germania, silica, etc. Other combinations of the metal oxides may also be used. The abrasive particles may have high purity, and an average diameter of about 120 nm to about 200 nm, with some embodiments having an average particle diameter of about 170 nm. Particle size distributions may ranging from about 5 nm to about 1000 nm, with some embodiments having particle sizes greater than 1 μm at the upper end of the range.

The additive combined with the abrasive may be a surfactant (e.g., an anionic, cationic, or non-ionic surfactant) such as polyacrylic acid and derivatives of polyacrylic acid (e.g., polyacrylic acid with substitutions at the carbonyl carbon or hydrocarbon backbone). Other additives may include dodecylbenzene sulfonate, cetyl ammonium salts, polyoxyethyelene alkylether, etc.

In step 106, the mixture of the abrasive and additive are then combined with water (e.g., de-ionized water). Alternatively the abrasive and additive may be separately added to the water (not shown). The water component controls the absolute concentration levels (measured here as % wt.) of the abrasive and additive. In one embodiment, for example, an amount of water is added such that the abrasive and additive together make up less than about 2%, by wt., of the slurry.

Concentrations of abrasive and additive may also be tailored to the types of IC chips being formed on the substrate. For example, a high selective slurry that has about 0.25% wt. abrasive and about 0.5% wt. additive may be used to polish DRAM wafers, and slurries having 0.5% wt. abrasive and 0.75% wt. additive may be used to polish logic wafers.

In addition to the abrasive, additive and water, other components may optionally also be applied to the present slurries. These other components may include pH adjusting agents such as a weak base or organic acid (e.g., an aliphatic or aromatic carboxylic acid) as well as inorganic acids and bases, such as ammonium or potassium hydroxide. These pH adjusting agents help maintain the CMP slurry in a desired pH range, such as from about 5 to about 9. In some embodiments of the present invention the additive may also act as a pH adjusting agent, such as polyacrylic acid.

If metals and other unoxidized or partially oxidized materials are present on the substrate, oxidizing and complexing agents, and corrosion inhibiting agents may also be added to the slurry. Examples of oxidizing and complexing agents include peroxide and percarboxylic acid containing compounds, such as peroxybenzoic acid, chlorobenzoic acid, peroxyacetic acid, peroxyformic acid, polyethylene glycol peroxy acids, and benzoyl peroxide. They may also include acids such as citric, lactic, tartaric, succinic and oxalic acid, as well as amino acids, amino sulfuric acids, amines, amides, diamines and alcoholamines. Specific examples include ethylenediaminetetraacetic acid, ethylenediamine, and methylformamide among others. When added, the oxidizing and complexing agents have concentrations in the slurry between about 0.2 weight percent and about 3.0 weight percent.

Corrosion inhibitors may include cyclic nitrogen containing compounds such as imidazole, benzotriazole, benzimidazole and benzothiazole. Derivatives of those compounds where the cyclic nitrogen compound is substituted with hydroxy, amino, imino, carboxy, mercapto, nitro and alkyl groups are also included. In one embodiment, the corrosion inhibitor is benzotriazole, mercaptobenzotriazole or 5-methyl-1-benzotriazole. Typically, when included, the concentration of the corrosion inhibitor in the composition is between about 0.02 weight percent and about 1.0 weight percent.

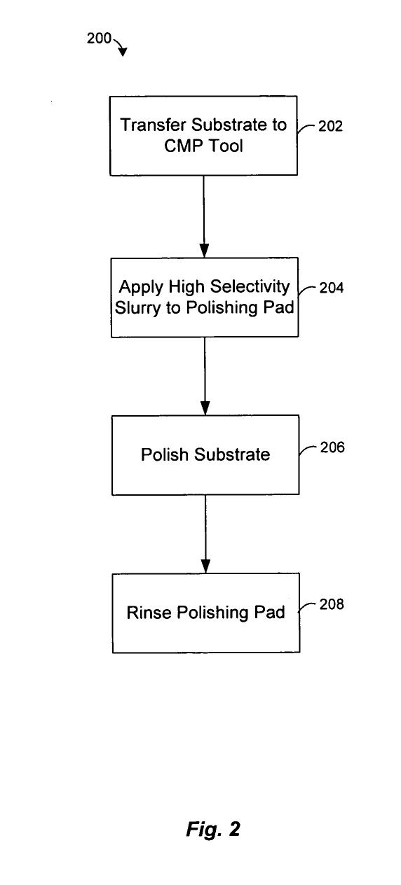

Referring now to FIG. 2, a flowchart with steps in a chemical-mechanical polishing method 200 according to an embodiment of the invention is shown. In this exemplary method, a substrate wafer is transferred to a polishing area of a chemical-mechanical polishing apparatus in step 202. In step 204, a CMP slurry is applied to a polishing pad on the polishing apparatus. The slurry may be applied at a rate of about 100 to about 300 ml/min during polishing. Typically, for 200 mm wafers, the slurry application rate is about 200 ml/min, and for 300 mm wafers the rate is about 250 ml/min.

As the slurry is applied to the polishing pad, the wafer may be polished in step 206 to remove excess oxide and planarize the substrate. During polishing, the substrate and polishing pad are urged together at a polishing pressure (e.g., about 2 psi to about 8 psi) for a time sufficient to remove at least a portion or all of the excess oxide disposed on the substrate surface.

The polishing may be done in a batch process where polishing starts and continues until completion on a single platen, or an inline polishing process where the wafer is polished on two or more different platens of the polishing apparatus. For example, polishing may start on a first platen for 30 to 60 seconds with a less selective slurry that removes bulk oxide. The substrate may then be transferred to a second platen for polishing with the high selectivity slurry for an additional 50 to 100 seconds. In some embodiments, such as when HSS polishing lasts longer than about 60 seconds, the substrate may be transferred to a third platen to finish the polishing. Total polishing times may range from about 100 to 200 seconds.

After the substrate is polished, the slurry is stopped and the polishing pad may be rinsed with de-ionized water or another rinsing fluid in step 208. The rinsing lasts long enough to remove most of the spent slurry, which typically may be between 5 and 30 seconds. The substrate wafer does not have to be removed from the polishing apparatus during the rinse step, and may also be rinsed of slurry and oxide debris.

### Exemplary Polishing Apparatus

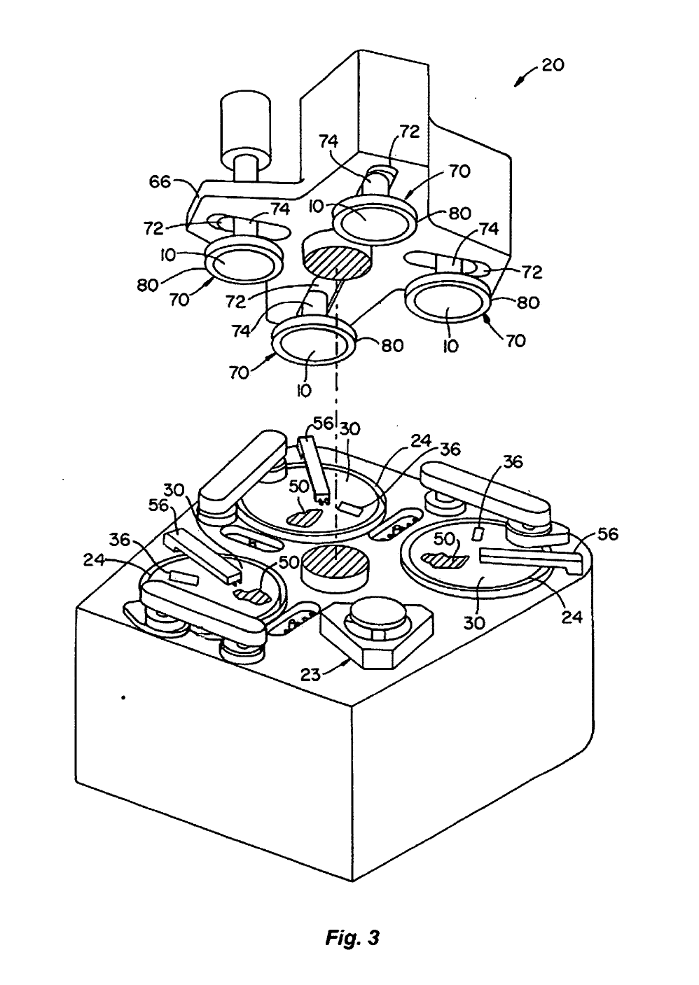

The present CMP slurries can be used with any standard CMP apparatus, such as apparatus 20 shown in FIG. 3. A substrate 10 may be loaded onto a transfer station 23 by a loading apparatus (not shown). The loading apparatus performs multiple functions, including washing the substrate, loading the substrate onto a carrier head, receiving the substrate from the carrier head, washing the substrate again and transferring the substrate back to the loading apparatus.

The transfer station 23 transfers the substrate to one of four carrier head systems 70. A carrier head 80 on a carrier head system 70 holds the substrate against polishing pad 30, which is located on top of a rotatable platen 24. Carrier head 80 evenly distributes a downward pressure across the back surface of the substrate using pressure source and transfers torque from the drive shaft 74 to the substrate.

A CMP slurry 50 may be stored in a polishing composition source, which is fluidly connected by a valve to a polishing composition delivery port 56. The polishing composition source, valve 58 and delivery port 56 comprise polishing composition supply system. Polishing composition 50 is delivered to the surface of the polishing pad 30 by supply system.

To polish substrate 10, the platen 24 is rotated about its central axis. At the same time, carrier head is rotated about its central axis 81 and translated laterally across the surface of the polishing pad through radial slot 72 formed in carousel support plate 66. An optical monitoring system is used to determine when to halt polishing.

The optical monitoring system is secured to platen 24 beneath hole. The optical monitoring system includes a light source and a detector. The light source generates a light beam, which propagates through transparent window 36 and slurry 50 to impinge upon the exposed surface of substrate 10. The light laser beam is projected from laser and detected by detector. Computer may be programmed to detect the polishing endpoint.

### EXAMPLES

Tests were conducted in which the number of scratches was counted on substrates polished using conventional CMP slurries, and slurries according to the invention. The substrates used included 200 mm oxide coated silicon wafers polished with a Mirra Mesa® CMP System available from Applied Materials, Inc. of Santa Clara, Calif., and 300 mm wafers polished with Reflexion® CMP System, also available form Applied Materials, Inc. The conventional CMP slurries used included Seimicron CES-333 1.0 with 1 wt. % cerium oxide abrasive and 1 wt. % aqueous surfactant solution additive, and CES-333 2.0 with 1 wt. % cerium oxide abrasive and 2 wt. % aqueous surfactant solution additive, both made by Seimi Chemical. Additional high selectivity slurries were made from HS-8005 ceria abrasive and 8102 GP or 8103 GPE aqueous surfactant solution additive (made by Hitachi Chemical Co. Ltd.) mixed with de-ionized water.

In order to provide an accurate comparison of the conventional and present slurries, polishing parameters were kept the same from run to run. For experimental runs with 200 mm substrate wafers, slurry was applied to the polishing pad at 200 mL/min while the platen was rotated at 77 rpm. For runs with 300 mm substrate wafers, slurry was applied at 250 mL/min while the platen was rotated at 87 rpm. For all runs, the polishing pad used was an IC1010 pad from Rodel (a subsidiary of Rhom and Haas), and the pad was contacted against the substrate wafer at a pressure of 2 to 4 psi. Each substrate wafer was polished to equivalent endpoints before being rinsed and examined for scratches.

The scratch count measurements included first scanning the surface of the substrate wafer with a laser beam and noting places on the surface where the laser light was scattered by a surface irregularity. Each surface irregularity was then manually reviewed with an optical microscope to determine whether the irregularity should be counted as an abrasive scratch. Irregularities counted as abrasive scratches included irregularities made up of multiple pockmarks, and irregularities made up of a single hole or indent having damage around the opening.

TABLE I
Scratch Count Data for CMP Slurries

| | | Abrasive | Additive | Scratch |
|---|---|---|---|---|
| Slurry Type | Wafer Size | (% wt.) | (% wt.) | Count |
| Asahi CES | 300 mm | 1.00 | 1.00 | 26 |
| Present Slurry | 300 mm | 0.50 | 0.75 | 17 |
| Present Slurry | 300 mm | 0.25 | 0.50 | 17 |
| Asahi CES | 300 mm | 1.00 | 1.00 | 39 |
| Present Slurry | 300 mm | 0.25 | 0.50 | 26 |
| Asahi CES | 300 mm | 1.00 | 1.00 | 41 |
| Present Slurry | 300 mm | 0.25 | 0.50 | 26 |
| Asahi CES | 300 mm | 1.00 | 1.00 | 14 |
| Present Slurry | 300 mm | 0.25 | 0.50 | 9 |
| Asahi CES | 300 mm | 1.00 | 1.00 | 50 |
| Present Slurry | 300 mm | 0.25 | 0.50 | 28 |
| Hitachi HSS | 200 mm | 1.56 | 2.26 | 100 |
| Present Slurry | 200 mm | 0.25 | 1.70 | 11 |

The data in Table I show a reduction in the scratch count of 35% or more for polishing runs using the present high selectivity slurries. The reduced scratch counts (as well as the reduced amount of slurry additive and abrasive consumed) are achieved without the dishing and nitride layer erosion that can occur when the conventional slurries are merely diluted with more water.

Having described several embodiments, it will be recognized by those of skill in the art that various modifications, alternative constructions, and equivalents may be used without departing from the spirit of the invention. Additionally, a number of well known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

As used herein and in the appended claims, the singular forms “a”, “and”, and “the” include plural referents unless the context clearly dictates otherwise. Thus, for example, reference to “a process” includes a plurality of such processes and reference to “the electrode” includes reference to one or more electrodes and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, or groups.

What is claimed is:

1. A chemical-mechanical polishing composition comprising less than about 1% wt. abrasive, an additive, and water, wherein a weigh percent of the additive is greater than a weight percent of the abrasive.

2. The chemical-mechanical polishing composition of claim 1, wherein the weight percent of the additive is about 1.5 times or more than the weight percent of the abrasive.

3. The chemical-mechanical polishing composition of claim 1, wherein the amount of abrasive is about 0.1 to about 0.3 wt. % and the amount of additive is about 0.45 to about 1 wt. %.

4. The chemical-mechanical polishing composition of claim 1, wherein the amount of abrasive is about 0.3% to about 0.5 wt. % and the amount of additive is about 0.75% to about 1 wt. %.

5. The chemical-mechanical polishing composition of claim 1, wherein the amount of abrasive is about 0.75 wt. % or less.

6. The chemical-mechanical polishing composition of claim 1, wherein a removal rate ratio for silicon oxide to silicon nitride is 5:1 or more.

7. The chemical-mechanical polishing composition of claim 1, wherein a removal rate ratio for silicon oxide to silicon nitride is 20:1 or more.

8. The chemical-mechanical polishing composition of claim 1, wherein the abrasive and additive comprise less than about 2 wt. % of the polishing composition.

9. The chemical-mechanical polishing composition of claim 1, wherein the abrasive comprises cerium oxide.

10. The chemical-mechanical polishing composition of claim 1, wherein the additive comprises a surfactant.

11. The chemical-mechanical polishing composition of claim 7, wherein the additive comprises polyacrylic acid.

12. The chemical-mechanical polishing composition of claim 1, wherein the composition has a pH range of about 5 to about 9.

13. A method of polishing a semiconductor substrate in a shallow trench isolation process, the polishing method comprising:
contacting the substrate with a polishing pad of a polishing apparatus while applying a high selectivity slurry to the polishing pad, wherein the slurry comprises less than about 1% wt. abrasive, an additive, and water, and wherein a weigh percent of the additive is greater than a weight percent of the abrasive.

14. The method of claim 13, wherein a weight percent of the additive is about 1.5 times or more than a weight percent of the abrasive.

15. The method of claim 13, wherein the polishing method comprises:
before the contacting of the substrate with the high selectivity slurry, contacting the substrate with another polishing pad of the polishing apparatus while applying a bulk oxide slurry to the pad, wherein the bulk slurry is used to remove bulk oxide from the semiconductor substrate.

16. The method of claim 13, wherein the amount of abrasive is about 0.1 to about 0.3 wt. % and the amount of additive is about 0.45 to about 1 wt. %.

17. The method of claim 13, wherein the amount of abrasive is about 0.3% to about 0.5 wt. % and the amount of additive is about 0.75% to about 1 wt. %.

18. The method of claim 13, wherein the abrasive comprises 0.75% by wt. or less of the polishing composition.

19. The method of claim 13, wherein the slurry is applied to the polishing pad at a rate of about 100 ml/min to about 300 ml/min.

20. The method of claim 13, wherein the semiconductor substrate is a wafer comprising films of silicon oxide and silicon nitride.

21. The method of claim 20, wherein the slurry has a removal rate ratio for the silicon oxide to the silicon nitride of about 20:1 or more.

22. The method of claim 20, wherein the silicon oxide is removed at a rate of about 1000 Å/min to about 5000 Å/min.

23. The method of claim 13, wherein the substrate has a scratch count of 28 or less after polishing.

24. The method of claim 13, wherein the slurry is premixed before being applied to the polishing pad.

25. The method of claim 13, wherein the semiconductor substrate is made into dynamic random access memory chips.

26. A method of making a chemical-mechanical polishing slurry composition, the method comprising:
adding together an abrasive, an additive and water to form the slurry, wherein a weigh percent of the additive is greater than a weight percent of the abrasive, and the abrasive and additive together comprise less than 2% by wt. of the slurry.

27. The method of claim 26, wherein a weight percent of the additive is about 1.5 times or more than a weight percent of the abrasive.

28. The method of claim 26, wherein the abrasive and the additive are separately added to the water.

29. The method of claim 26, wherein the abrasive and the additive are mixed together before being added to the water.

30. The method of claim 26, wherein the amount of abrasive is about 0.1 to about 0.3 wt. % and the amount of additive is about 0.45 to about 1 wt. %.

31. The method of claim 26, wherein the amount of abrasive is about 0.3% to about 0.5 wt. % and the amount of additive is about 0.75% to about 1 wt. %.
